(19) United States
(12) Patent Application Publication
(10) Pub. No.: US 2008/0126458 A1
(43) Pub. Date: May 29, 2008

(54) Apparatus and Methods for Generating Random Signals

(75) Inventor: Soon Kyun Shin, Gyeonggi-do (KR)

Correspondence Address: MYERS BIGEL SIBLEY & SAJOVEC, PO BOX 37428, RALEIGH, NC, 27627, US

(73) Assignee: Samsung Electronics Co., Ltd.

(21) Appl. No.: 11/622,193

(22) Filed: Jan. 11, 2007

(30) Foreign Application Priority Data
Aug. 14, 2006 (KR) 2006-76570

(51) Int. Cl. G06F 7/58; H03K 3/84; H03B 29/00

(52) U.S. Cl. 708/255; 331/78; 327/164

(57) ABSTRACT

A random signal generator circuit includes a thermal noise generator circuit and a self-biased inverter having an input coupled to the thermal noise generator circuit and to a feedback resistor coupled to an output of the self-biased inverter, the self-biased inverter configured to produce a sensed noise signal at the output responsive to thermal noise generated by the thermal noise generator circuit. An amplifier circuit is coupled to the output of the self-biased inverter and configured to amplify the sensed noise signal to produce a saturated random signal. The saturate random signal may be sampled, e.g., with a flip-flop, to generate a random binary signal that may be used for random number generation.

### CROSS-REFERENCE TO RELATED APPLICATION

This application claims the benefit of Korean Patent Application No. 2006-0076570, filed Aug. 11, 2006, the disclosure of which is hereby incorporated herein by reference in its entirety.

### BACKGROUND

The present invention relates to circuits and methods for generating random signals, such as random signals that may be used to generate random numbers.

Random (or pseudorandom) number generation is used in many electronics applications, such as computer and telecommunications applications. In some applications, a random bit stream, i.e., a sequence of binary signals lacking a discernable pattern or repetition, may generated from a source that naturally exhibits random or pseudorandom characteristics.

A variety of circuits for generating random signals have been proposed. U.S. Pat. No. 7,007,060 to Miller, Jr. describes methods and circuits for generating a random signal based on thermal noise of a complementary metal oxide semiconductor (CMOS) device. The techniques described involve feeding outputs from a pair of identical thermal noise generators into a differential amplifier, which measures and amplifies a difference between the outputs. The amplified difference is compared with a reference voltage to generate a random bit stream. Korean Patent Application No. 2004-093872 describes a similar approach using thermal noise sensed by a differential amplifier to drive a voltage-controlled oscillator (VCO) that clocks a flip-flop that receives a data signal from another VCO.

### SUMMARY

In some embodiments of the present invention, a random signal generator circuit includes a thermal noise generator circuit and a self-biased inverter having an input coupled to the thermal noise generator circuit and to a feedback resistor coupled to an output of the self-biased inverter. The self-biased inverter is configured to produce a sensed noise signal at the output responsive to thermal noise generated by the thermal noise generator circuit. An amplifier circuit is coupled to the output of the self-biased inverter and configured to amplify the sensed noise signal to produce a saturated random signal.

According to further embodiments of the present invention, the amplifier circuit includes a first amplifier circuit coupled to the output of the self-biased inverter and configured to amplify the sensed noise signal to produce an amplified noise signal and a second amplifier circuit AC coupled to the first amplifier circuit and configured to produce the saturated random signal responsive to the amplified noise signal. The first amplifier circuit may include an inverter or a plurality of cascaded inverters. The second amplifier circuit may include a cascade combination of a self-biased inverter and at least one inverter. The second amplifier circuit may include a plurality of AC coupled amplifier circuits. Each of the plurality of AC coupled amplifier circuits may include a cascade combination of a self-biased inverter and at least one inverter.

In some embodiments, a gain of the first amplifier circuit may be substantially greater than a gain of the self-biased inverter, and a gain of the second amplifier circuit may be substantially greater than the gain of the first amplifier circuit. The self-biased inverter may include a self-biased CMOS inverter, the first amplifier circuit may include a CMOS inverter or a plurality of cascaded CMOS inverters, and the second amplifier circuit may include a cascade combination of a self-biased CMOS inverter and at least one CMOS inverter.

In further embodiments, the thermal noise generator circuit includes a thermal noise generating resistor coupled to the input of the self-biased inverter. The thermal noise generator circuit may include a series combination of a resistor and a capacitor coupled between the input of the self-biased inverter and a signal ground node.

In additional embodiments, a sampler circuit may be coupled to the amplifier circuit and may be configured produce a random binary signal from the saturated random signal responsive to a clock signal. The sampler circuit may include a flip-flop. Further embodiments provide random number generator circuits including a random signal generator circuit as discussed above.

Additional embodiments provide a random signal generator circuit including a thermal noise generator circuit and a first single-ended amplifier circuit coupled to the thermal noise generator circuit and configured to sense and amplify a noise signal thereof to produce an amplified noise signal. A second single-ended amplifier circuit is AC coupled to the first single-ended amplifier circuit and configured to produce a saturated random signal responsive to the amplified noise signal.

The first single-ended amplifier circuit may include a self-biased inverter having an input coupled to the thermal noise generator circuit and configured to produce a sensed noise signal at an output thereof responsive to thermal noise generated by the thermal noise generator circuit and at least one inverter coupled to the output of the self-biased inverter and configured to generate the amplified noise signal from the sensed noise signal. The second single-ended amplifier circuit may include a cascade combination of a self-biased inverter and at least one inverter. The second single-ended amplifier circuit may include a plurality of AC coupled amplifier circuits. Each of the plurality of AC coupled amplifier circuits may include a cascade combination of a self-biased inverter and at least one inverter.

In further embodiments, the thermal noise generator circuit may include a resistor and the first single-ended amplifier circuit may be configured to generate the amplified noise signal responsive to a thermal noise voltage developed across the resistor. The thermal noise generator circuit may include a series combination of a resistor and a capacitor coupled between the input of the first single-ended amplifier circuit and a signal ground node. The random signal generator circuit may further include a sampler circuit configured to generate a random binary signal from the saturated random signal.

Some embodiments of the present invention include methods wherein a thermal noise generator circuit is coupled to an input of a self-biased inverter to generate a sensed noise signal at an output thereof. The sensed noise signal is applied to a first amplifier circuit to produce an unsaturated amplified noise signal. The unsaturated noise signal is AC coupled to a second amplifier circuit to produce a saturated random signal. A random binary signal may be generated from the saturated random signal, e.g., by sampling the saturated random signal responsive to a clock signal to produce the random binary signal.

### BRIEF DESCRIPTION OF THE DRAWINGS

FIG. 1 is a schematic diagram illustrating a random number generator circuit according to some embodiments of the present invention.

FIG. 2 is a schematic diagram illustrating a random signal generator circuit according to some embodiments of the present invention.

FIG. 3 is a schematic diagram illustrating a noise source and self-biased inverter circuit for use in a random signal generator circuit according to some embodiments of the present invention.

FIG. 4 is a schematic diagram illustrating a random signal generator circuit according to some embodiments of the present invention.

FIGS. 5a-c are waveform diagrams illustrating exemplary operations of the random signal generator circuit of FIG. 4.

FIG. 6 is a schematic diagram illustrating a random signal generator circuit according to further embodiments of the present invention.

FIG. 7 is a schematic diagram illustrating a sampler circuit according to some embodiments of the present invention.

FIG. 8 is a waveform diagram illustrating exemplary operations of the sampler circuit of FIG. 7.

### DETAILED DESCRIPTION

The invention is described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the sizes or configurations of elements may be idealized or exaggerated for clarity.

It will be understood that when an element is referred to as being “connected to” or “coupled to” another element, it may be directly connected or coupled to the other element or intervening elements may be present. In contrast, when an element is referred to as being “directly connected to” or “directly coupled to” another element, there are no intervening elements present. Like numbers refer to like elements throughout. As used herein, the term “and/or” includes any and all combinations of one or more of the associated listed items.

It will be understood that, although the terms first, second, third etc. may be used herein to describe various elements, components and/or sections, these elements, components and/or sections should not be limited by these terms. These terms are only used to distinguish one element, component, or section from another element, region or section. Thus, a first element, component or section discussed below could be termed a second element, component or section without departing from the teachings of the present invention.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and this specification, and will not be interpreted in an idealized or overly formal sense unless expressly so defined herein.

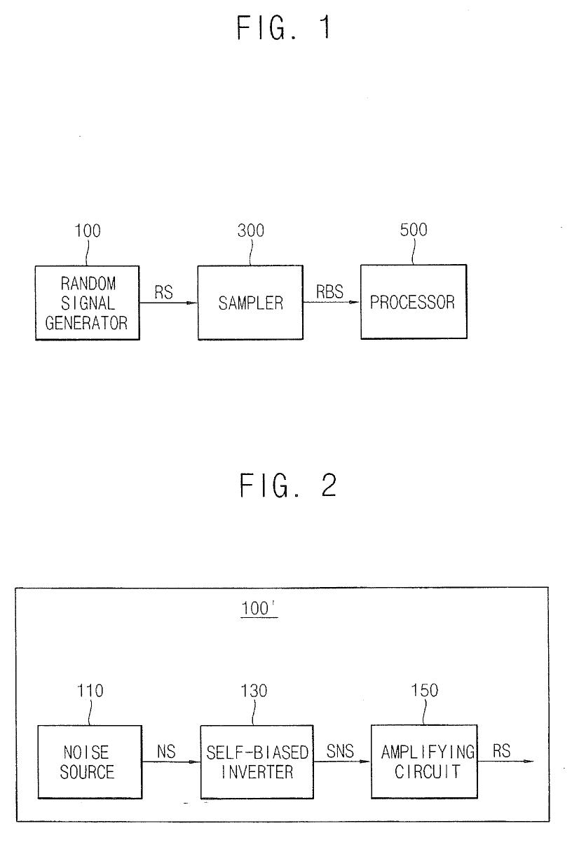

FIG. 1 illustrates a random signal generator circuit 100 that generates a random signal RS. An output of the random signal generator circuit 100 is coupled to an input of a sampler circuit 300, which samples the random signal RS to produce a random binary signal RBS, e.g., a digital signal that randomly transitions between first and second states. The random binary signal RBS may be provided, for example, to a processor 500 or other circuitry. For example, the processor 500 may be configured to generate random numbers from the random binary signal RBS, e.g., by loading the binary values of the random binary signal RBS into a shift register to generate random multi-bit words. It will be appreciated that, in other embodiments, circuitry other than a processor may be similarly employed to produce random numbers.

FIG. 2 illustrates an exemplary implementation of a random signal generator circuit 100′ according to some embodiments of the present invention. The random signal generator circuit 100′ includes a noise source circuit 110 that generates a noise signal NS. The random signal generator circuit 100′ further includes a self-biased inverter circuit 130 that senses the noise signal NS and responsively generates a sensed noise signal SNS. The sensed noise signal SNS is provided to an amplifier circuit 150, which amplifies the sensed noise signal SNS to produce a random signal RS.

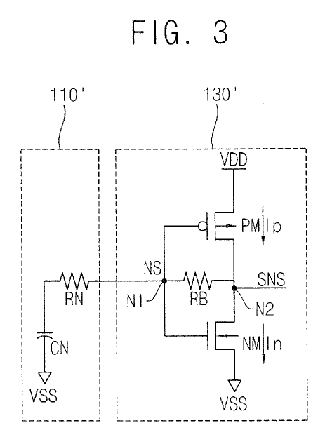

FIG. 3 illustrates exemplary implementations of a noise source circuit 110′ and a self-biased inverter circuit 130′ according to further embodiments of the present invention. The noise source circuit 110′ includes a noise capacitor CN connected in series with a noise resistor RN. The noise resistor RN is coupled to an input node N1 of the self-biased inverter circuit 130′. The self-biased inverter circuit 130′ includes a PMOS transistor PM having a gate coupled to the input node N1, a source coupled to a power supply node VDD, and a drain coupled to an output node N2. The self-biased inverter circuit 130′ further includes an NMOS transistor NM having a gate coupled to the input node N1, a source coupled to the output node N2 and a drain coupled to a power supply ground node VSS. The self-biased inverter circuit 130′ further includes a bias resistor RB coupled between the input node N1 and the output node N2.

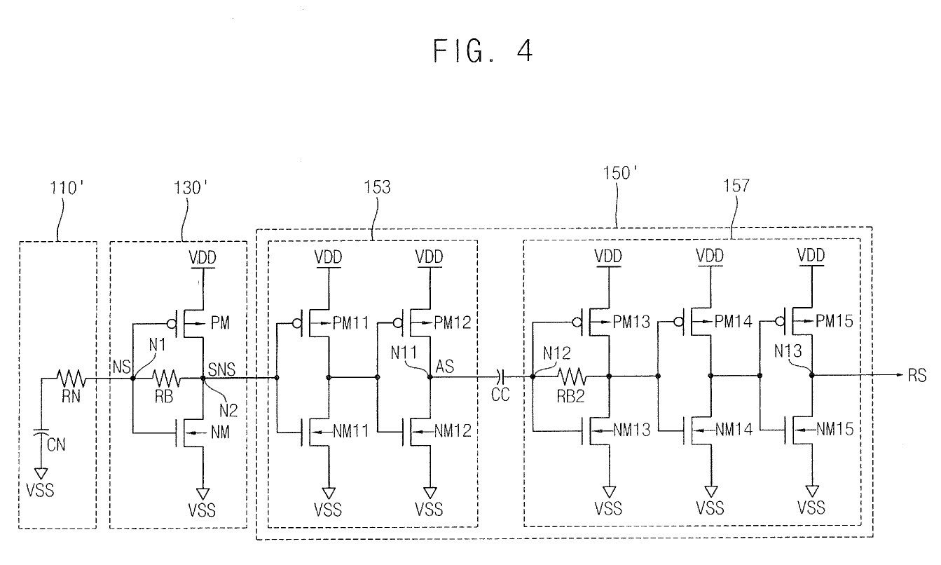

FIG. 4 illustrates an exemplary amplifier circuit 150′ that may be coupled to the output of the self-biased inverter circuit 130′. The amplifier circuit 150′ includes a first stage 153 that includes two serially connected inverter circuits including respective complementary PMOS/NMOS transistor pairs PM11/NM11, PM12/NM12. An output node N11 of the first stage 153 is coupled to an input node N12 of a second stage 157 by a coupling capacitor CC. The second stage 157 includes a self-biased inverter circuit including complementary transistors PM13, NM13 and a bias resistor RB2, and two serially connected inverter circuits including respectively complementary transistor pairs PM14/NM14, PM15/NM15.

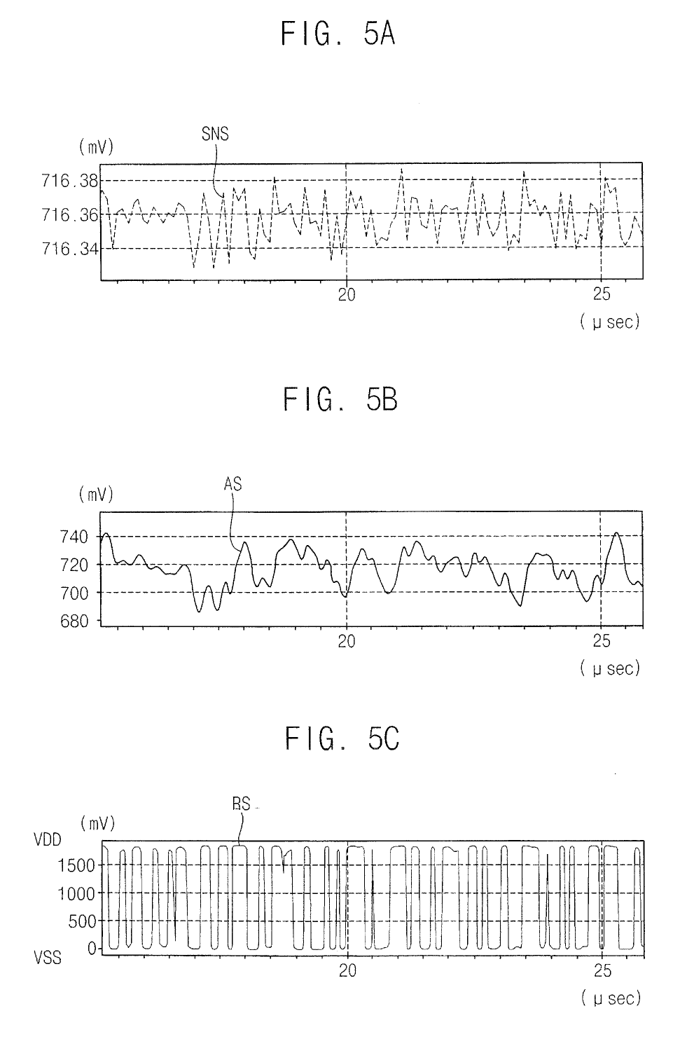

Referring to FIGS. 4 and 5a-c, a sensed noise signal SNS generated by the self-biased inverter circuit 130′ is fed to the first stage 153, which responsively generates an amplified signal AS. The second stage 153 further amplifies the amplified signal AS to produce a random signal RS at an output node N13. As shown in FIG. 5c, in contrast to the unsaturated amplified signal AS, the random signal RS is saturated, i.e., the signal excursions of the amplified signal AS are amplified such that the all or most of the corresponding transitions of the random signal RS extend between the power supply voltage VDD and the ground voltage VSS, producing a waveform that is “clipped” such that the random signal is predominantly at the power supply voltage VDD or the ground voltage VSS, which short transitions therebetween. As shown below, such a saturated signal may be sampled using digital circuitry, such as a flip-flop. The coupling capacitor CC serves to block a DC component of the amplified signal AS before amplification by the second stage 157.

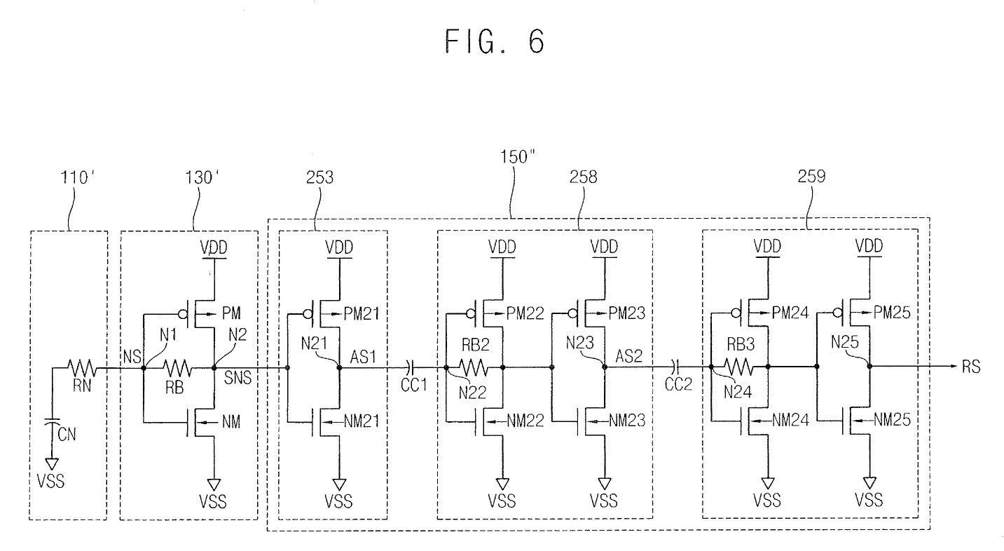

FIG. 6 illustrates an exemplary amplifier circuit 150″ that may be coupled to the output of the self-biased inverter circuit 130′ according to further embodiments of the present invention. The amplifier circuit 150″ includes a first stage 253 that includes a single inverter comprising a complementary transistor pair PM21/NM21. An output node N21 of the first stage 253 is AC coupled by a first coupling capacitor CC1 to an input node N22 of a second stage 258, which includes a series combination of a self-biased inverter circuit, including complementary transistors PM22, NM22 and a bias resistor RB2, and an inverter circuit, including a complementary PMOS/NMOS transistor pair PM23, NM23. An output node N23 of the second stage 258 is AC coupled by a second coupling capacitor CC2 to an input node N24 of a third stage 259, which includes a series combination of a self-biased inverter circuit, including complementary transistors PM24, NM24 and a bias resistor RB3, and an inverter circuit, including a complementary PMOS/NMOS transistor pair PM25, NM25.

A sensed noise signal SNS generated by the self-biased inverter circuit 130′ is fed to the input of the first stage 253, which responsively generates a first amplified signal AS1 at the output node N21. The second stage 253 further amplifies the amplified signal AS1 to produce a second amplified signal AS2 at the output node N23. The third stage 259 further amplifies the second amplified signal AS2 to generate a random signal RS at the output node N25. The AC coupling capacitors CC1, CC2 serve to block DC components of the amplified signals AS1, AS2 before amplification by the succeeding stages.

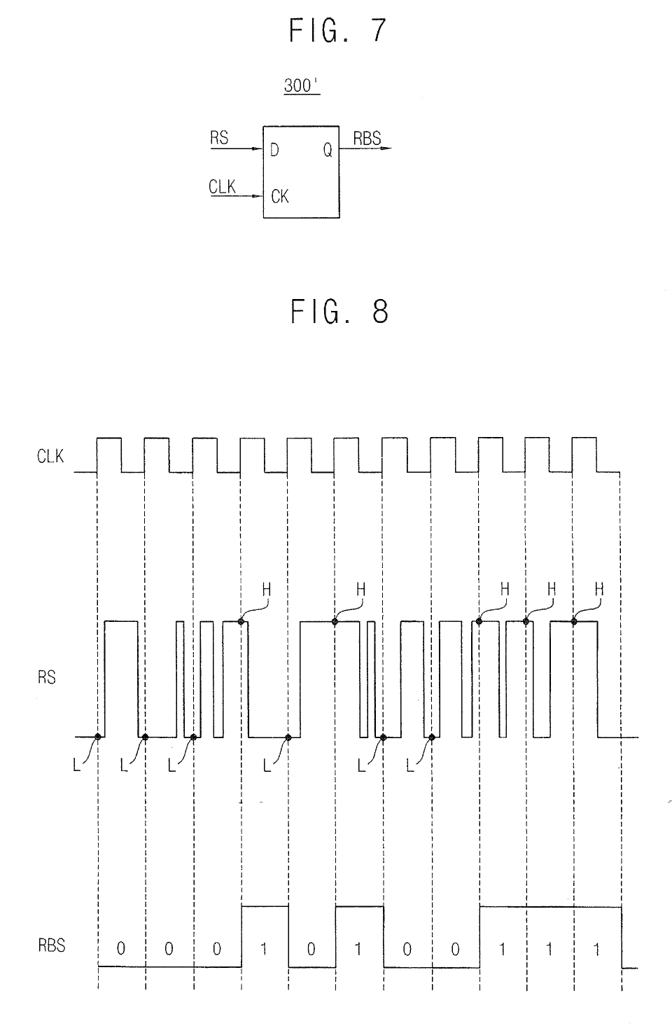

Referring again to FIG. 1, the sampler circuit 300 used to sample the random signal RS to produce the random binary signal RBS may take any of a number of different forms. For example, FIG. 7 illustrates sampler circuit in the form of a flip-flop 300′ that includes a data input D that receives a random signal RS and that samples the random signal RS synchronous with a clock signal CLK applied to a clock signal input CK to generate a random binary signal RBS at a data output Q that is synchronized with the clock signal CLK. For example, FIG. 8 shows binary values “0” and “1” of the random binary signal RBS generated by sampling “low” (L) and “high” (h) levels of the random signal RS at rising edges of the clock signal CLK. The synchronized random binary signal RBS may be particularly suitable for, for example, clocking into a register for generation of random multi-bit words.

The foregoing is illustrative of the present invention and is not to be construed as limiting thereof. Although a few exemplary embodiments of this invention have been described, those skilled in the art will readily appreciate that many modifications are possible in the exemplary embodiments without materially departing from the novel teachings and advantages of this invention. Accordingly, all such modifications are intended to be included within the scope of this invention as defined in the claims. Therefore, it is to be understood that the foregoing is illustrative of the present invention and is not to be construed as limited to the specific embodiments disclosed, and that modifications to the disclosed embodiments, as well as other embodiments, are intended to be included within the scope of the appended claims.

What is claimed is:

1. A random signal generator circuit comprising:
a thermal noise generator circuit;
a self-biased inverter circuit having an input coupled to the thermal noise generator circuit and to a feedback resistor coupled to an output of the self-biased inverter circuit, the self-biased inverter circuit configured to produce a sensed noise signal at the output responsive to thermal noise generated by the thermal noise generator circuit; and
an amplifier circuit coupled to the output of the self-biased inverter circuit and configured to amplify the sensed noise signal to produce a saturated random signal.

2. The random signal generator circuit of claim 1, wherein the amplifier circuit comprises:
a first amplifier circuit coupled to the output of the self-biased inverter circuit and configured to amplify the sensed noise signal to produce an amplified noise signal; and
a second amplifier circuit AC coupled to the first amplifier circuit and configured to produce the saturated random signal responsive to the amplified noise signal.

3. The random signal generator circuit of claim 2, wherein the first amplifier circuit comprises an inverter circuit.

4. The random signal generator circuit of claim 3, wherein the first amplifier circuit comprises a plurality of cascaded inverter circuits.

5. The random signal generator circuit of claim 2, wherein the second amplifier circuit comprises a cascade combination of a self-biased inverter circuit and at least one inverter circuit.

6. The random signal generator circuit of claim 2, wherein the second amplifier circuit comprises a plurality of AC coupled amplifier circuits.

7. The random signal generator circuit of claim 6, wherein each of the plurality of AC coupled amplifier circuits comprises a cascade combination of a self-biased inverter circuit and at least one inverter circuit.

8. The random signal generator circuit of claim 2, wherein a gain of the first amplifier circuit is substantially greater than a gain of the self-biased inverter circuit, and wherein a gain of the second amplifier circuit is substantially greater than the gain of the first amplifier circuit.

9. The random signal generator circuit of claim 2:
wherein the self-biased inverter circuit comprises a self-biased CMOS inverter circuit:
wherein the first amplifier circuit comprises a CMOS inverter circuit or a plurality of cascaded CMOS inverter circuits; and
wherein the second amplifier circuit comprises a cascade combination of a self-biased CMOS inverter circuit and at least one CMOS inverter circuit.

10. The random signal generator circuit of claim 1, wherein the thermal noise generator circuit comprises a thermal noise generating resistor coupled to the input of the self-biased inverter circuit.

11. The random signal generator circuit of claim 10, wherein the thermal noise generator circuit comprises a series combination of a resistor and a capacitor coupled between the input of the self-biased inverter circuit and a signal ground node.

12. The random signal generator circuit of claim 1, further comprising a sampler coupled to the amplifier circuit and configured to produce a random digital signal from the saturated random signal responsive to a clock signal.

13. The random signal generator circuit of claim 12, wherein the sampler comprises a flip-flop.

14. A random number generator circuit including the random signal generator circuit of claim 1.

15. A random signal generator circuit comprising:
a thermal noise generator circuit;
a first single-ended amplifier circuit coupled to the thermal noise generator circuit and configured to sense and amplify a noise signal thereof to produce an amplified noise signal; and
a second single-ended amplifier circuit AC coupled to the first single-ended amplifier circuit and configured to produce a saturated random signal responsive to the amplified noise signal.

16. The random signal generator circuit of claim 15, wherein the first single-ended amplifier circuit comprises:
a self-biased inverter circuit having an input coupled to the thermal noise generator circuit and configured to produce a sensed noise signal at an output thereof responsive to thermal noise generated by the thermal noise generator circuit; and
at least one inverter circuit coupled to the output of the self-biased inverter circuit and configured to generate the amplified noise signal from the sensed noise signal.

17. The random signal generator circuit of claim 15, wherein the second single-ended amplifier circuit comprises a cascade combination of a self-biased inverter circuit and at least one inverter circuit.

18. The random signal generator circuit of claim 15, wherein the second single-ended amplifier circuit comprises a plurality of AC coupled amplifier circuits.

19. The random signal generator circuit of claim 18, wherein each of the plurality of AC coupled amplifier circuits comprises a cascade combination of a self-biased inverter circuit and at least one inverter circuit.

20. The random signal generator circuit of claim 15, wherein the thermal noise generator circuit comprises a resistor and wherein the first single-ended amplifier circuit is configured to generate the amplified noise signal responsive to a thermal noise voltage developed across the resistor.

21. The random signal generator circuit of claim 15, wherein the thermal noise generator circuit comprises a series combination of a resistor and a capacitor coupled between the input of the first single-ended amplifier circuit and a signal ground node.

22. The random signal generator circuit of claim 15, further comprising a sampler configured to generate a random digital signal from the saturated random signal.

23. A random number generator circuit including the random signal generator circuit of claim 1.

24. A method comprising:
coupling a thermal noise generator circuit to an input of a self-biased inverter circuit to generate a sensed noise signal at an output thereof,
applying the sensed noise signal to a first amplifier circuit to produce an unsaturated amplified noise signal; and
AC coupling the unsaturated noise signal to a second amplifier circuit to produce a saturated random signal.

25. The method of claim 24, wherein the first amplifier circuit comprises an inverter circuit.

26. The method of claim 25, wherein the first amplifier circuit comprises a plurality of cascaded inverter circuits.

27. The method of claim 24, wherein the second amplifier circuit comprises a cascade combination of a self-biased inverter circuit and at least one inverter circuit.

28. The method of claim 24, wherein the second amplifier circuit comprises a plurality of AC coupled amplifier circuits.

29. The method of claim 28, wherein each of the plurality of AC coupled amplifier circuits comprises a cascade combination of a self-biased inverter circuit and at least one inverter circuit.

30. The method of claim 24, wherein coupling a thermal noise generator circuit to an input of a self-biased inverter circuit to generate a sensed noise signal at an output thereof comprises generating the sensed noise signal responsive to a thermal noise voltage developed across a resistor of the thermal noise generator circuit.

31. The method of claim 30, wherein the thermal noise generator circuit comprises a series combination of a resistor and a capacitor coupled between the input of the self-biased inverter circuit and a signal ground node.

32. The method of claim 24, wherein a gain of the first amplifier circuit is substantially greater than a gain of the self-biased inverter circuit, and wherein a gain of the second amplifier circuit is substantially greater than the gain of the first amplifier circuit.

33. The method of claim 24:
wherein the self-biased inverter circuit comprises a self-biased CMOS inverter circuit:
wherein the first amplifier circuit comprises a CMOS inverter circuit or a plurality of cascaded CMOS inverter circuits; and
wherein the second amplifier circuit comprises a cascade combination of a self-biased CMOS inverter circuit and at least one CMOS inverter circuit.

34. The method of claim 24, further comprising generating a random digital signal from the saturated random signal.

35. The method of claim 34, wherein generating a random digital signal from the saturated random signal comprises sampling the saturated random signal responsive to a clock signal to produce the random digital signal.

36. The method of claim 35, wherein sampling the saturated random signal responsive to a clock signal to produce the random digital signal comprises sampling the saturated random signal using a flip-flop.

37. The method of claim 34, further comprising generating a random number from the random digital signal.
